(19) United States
(12) Patent Application Publication
(10) Pub. No.: US 2025/0221158 A1
(43) Pub. Date: Jul. 3, 2025

(54) DISPLAY DEVICE

(71) Applicant: LG DISPLAY CO., LTD., Seoul (KR)

(72) Inventors: Hyeoksoo Jang, Paju-si (KR); JinHo Park, Paju-si (KR)

(73) Assignee: LG DISPLAY CO., LTD., Seoul (KR)

(21) Appl. No.: 18/670,385

(22) Filed: May 21, 2024

(30) Foreign Application Priority Data
Dec. 27, 2023 (KR) 10-2023-0192774

(51) Int. Cl. H10K 50/18; H10K 50/85; H10K 59/00; H10K 59/35

(52) U.S. Cl. CPC H10K 50/181; H10K 50/85; H10K 59/771; H10K 59/35

(57) ABSTRACT

A display device in which each of first to third light emitting devices includes a first electrode disposed on a substrate, a first hole transport layer disposed on the first electrode, and a first light emitting layer disposed on the first hole transport layer, wherein each of the first and second light emitting devices includes a first optical layer disposed between the first hole transport layer and the first light emitting layer, and a thickness of the first optical layer of the first light emitting device is the same as a thickness of the first optical layer of the second light emitting device.

### CROSS-REFERENCE TO RELATED APPLICATIONS

This application claims the benefit of the Korean Patent Application No. 10-2023-0192774, filed on Dec. 27, 2023, which is hereby incorporated by reference as if fully set forth herein.

### BACKGROUND

### Field of the Invention

The present disclosure relates to a display device.

### Description of the Related Art

As the information society develops, the demand for display devices increases. Accordingly, various display devices such as a liquid crystal display (LCD), a plasma display (PDP), and an organic light emitting display (OLED) have recently been used. Among the display devices, an organic light emitting display device is a self-emission type, and has advantages such as superior viewing angle and contrast ratio compared to LCD, light weight and thinness are possible because no separate backlight is required, and power consumption is advantageous. In addition, the organic light emitting display device has the advantage of being able to drive a DC low voltage, fast response speed, and especially low manufacturing cost.

In addition, an organic light emitting device used in the organic light emitting display device includes a plurality of organic layers and a plurality of a metal layers, and a process of forming each material layer is required. Recently, research has been conducted to simplify the process of manufacturing the organic light emitting device.

### SUMMARY

Accordingly, one object of the present disclosure is to address the above noted and other problems.

Another object of the present disclosure is to provide an organic light-emitting device with improved device characteristics while simplifying the process and a display device including the same.

To achieve these and other advantages and in accordance with the purpose of the present invention, as embodied and broadly described herein, the present invention provides in one aspect a display device having a substrate including a first sub-pixel, a second sub-pixel and a third sub-pixel, a first light emitting device disposed in the first sub-pixel, a second light emitting device disposed in the second sub-pixel, and a third light emitting device disposed in the third sub-pixel, wherein each of the first to third light emitting devices includes a first electrode disposed on the substrate, a first hole transport layer disposed on the first electrode, and a first light emitting layer disposed on the first hole transport layer, each of the first and second light emitting devices includes a first optical layer disposed between the first hole transport layer and the first light emitting layer, and a thickness of the first optical layer of the first light emitting device is the same as a thickness of the first optical layer of the second light emitting device.

Further scope of applicability of the present invention will become apparent from the detailed description given hereinafter. However, the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings, which are given by illustration only, and thus are not limitative of the present invention, and wherein:

FIG. 1 is a cross-sectional view of a plurality of sub-pixels of a display device according to a first embodiment of the present invention.

FIG. 2 is a cross-sectional view of a plurality of sub-pixels of a display device according to a second embodiment of the present invention.

FIG. 3 is a cross-sectional view of a plurality of sub-pixels of a display device according to a third embodiment of the present invention.

FIG. 4 is a cross-sectional view of a plurality of sub-pixels of a display device according to a fourth embodiment of the present invention.

FIG. 5 is a cross-sectional view of a plurality of sub-pixels of a display device according to a fifth embodiment of the present invention.

FIG. 6 is a cross-sectional view of a plurality of sub-pixels of a display device according to a sixth embodiment of the present invention.

FIG. 7 is a cross-sectional view of a plurality of sub-pixels of a display device according to a seventh embodiment of the present invention.

FIG. 8 is a cross-sectional view of a plurality of sub-pixels of a display device according to an eighth embodiment of the present invention.

FIG. 9 is another cross-sectional view of a plurality of sub-pixels of a display device according to a first embodiment of the present invention.

### DETAILED DESCRIPTION OF THE DISCLOSURE

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. When ‘comprise’, ‘have’ and ‘include’ described in the present disclosure are used, another portion can be added unless ‘only˜’ is used. The terms of a singular form can include plural forms unless referred to the contrary.

In construing an element, the element is construed as including an error band although there is no explicit description. In describing a position relationship, for example, when the position relationship is described as ‘upon˜’, ‘above˜’, ‘below˜’ and ‘next to˜’, one or more portions can be disposed between two other portions unless ‘just’ or ‘direct’ is used. Although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in a co-dependent relationship. Hereinafter, embodiments of the present disclosure will be described in detail with reference to the accompanying drawings.

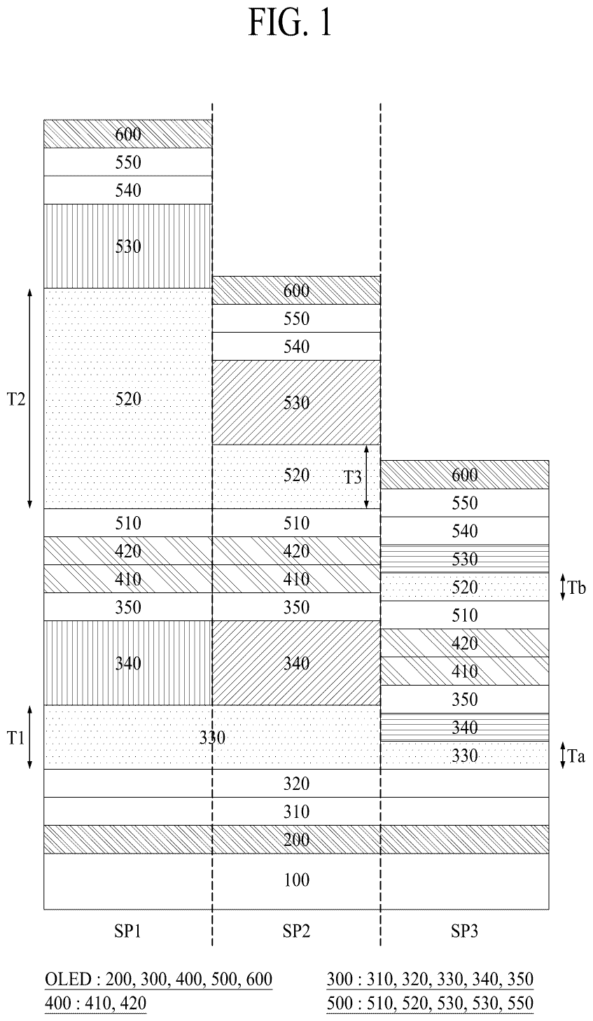

In more detail, FIG. 1 is a cross-sectional view of a plurality of sub-pixels SP of a display device according to a first embodiment of the present invention. Referring to FIG. 1, a substrate 100 can is divided into a plurality of sub-pixels SP. As shown, the plurality of sub-pixels SP can include a first sub-pixel SP1, a second sub-pixel SP2 and a third sub-pixel SP3. In particular, the first sub-pixel SP1 can emit red light, the second sub-pixel SP2 can emit green light, and the third sub-pixel SP3 can emit blue light.

A plurality of organic light emitting devices OLED can be disposed on the substrate 100can and include a first organic light emitting device OLED1, a second organic light emitting device OLED2 and a third organic light emitting device OLED3. The first organic light emitting device OLED1 can be disposed in the first sub-pixel SP1, the second organic light emitting device OLED2 can be disposed in the second sub-pixel SP, and the third organic light emitting device OLED3 can be disposed in the third sub-pixel SP3.

In addition, the substrate 100 can be made of glass or plastic, but is not limited thereto. Further, the display device according to the first embodiment of the present invention can be made of a top emission type in which the emitted light is emitted upward. Therefore, as the material of the substrate 100, not only a transparent material but also an opaque material can be used. Each of the first to third organic light emitting devices OLED1 to OLED3 can also include a first electrode 200, a first stack 300, a charge generation layer 400, a second stack 500, and a second electrode 600.

As shown in FIG. 1, the first electrode 200 is disposed on the substrate 100 can in each of the first to third sub-pixels SP1 to SP3. The first electrode 200 can provides holes to the first stack 300. Also, the first electrode 200 of the first to third organic light emitting diodes OLED1 to OLED3 include the same material and can be formed to have the same or substantially same thickness, but is not limited thereto.

In addition, the first electrode 200 can include a transparent conductive material such as an indium tin oxide (ITO) or an indium zinc oxide (IZO). Alternatively, the first electrode 200 can include a metal material such as aluminum (Al), silver (Ag), copper (Cu), molybdenum (Mo), titanium (Ti), tungsten (W), or chromium (Cr), or an alloy thereof. Also, although illustrated as a single layer, the first electrode 200 can be formed of multiple layers.

Further, the first stack 300 of each of the first to third organic light emitting devices OLED1 to OLED3 can be disposed on the first electrode 200. Also, the first stack 300 of each of the first to third organic light emitting devices OLED1 to OLED3 can include a first hole injection layer 310, a first hole transport layer 320, a first optical layer 330, a first light emitting layer 340, and a first electron transport layer 350.

In the first to third organic light emitting devices OLED1 to OLED3, the first hole injection layer 310 is disposed on the first electrode 200, and holes provided from the first electrode 200 can be easily injected into the first light emitting layer 340. Also, the first hole injection layer 310 of the first to third organic light emitting devices OLED1 to OLED3 includes the same material and can be formed with the same or substantially same thickness, but is not limited thereto.

In the first to third organic light emitting devices OLED1 to OLED3, the first hole transport layer 320 is disposed on the first hole injection layer 310, and holes provided from the first electrode 200 can be easily transported to the first light emitting layer 340. Also, the first hole transport layer 320 of the first to third organic light emitting devices OLED1 to OLED3 includes the same material and can be formed with the same or substantially same thickness, but is not limited thereto.

In the first to third organic light emitting devices OLED1 to OLED3, the first optical layer 330 can be disposed on the first hole transport layer 320. In this instance, among the first optical layers 330 of the first to third organic light emitting devices OLED1 to OLED3, a thickness of one can be the same as or similar to a thickness of another and can be different from a thickness of the other. That is, among the first optical layers 330 of the first to third organic light emitting devices OLED1 to OLED3, the two first optical layers 330 can have the same or substantially same thickness, and the other first optical layer 330 can have different thicknesses.

Specifically, a thickness T1 of the first optical layer 330 of the first and second organic light emitting devices OLED1 and OLED2 can be the same or substantially same. Also, the thickness T1 of the first optical layer 330 of the first and second organic light emitting devices OLED1 and OLED2 can be formed to be about four times a thickness Ta of the first optical layer 330 of the third organic light emitting device OLED3. For example, when the thickness Ta of the first optical layer 330 of the third organic light emitting device OLED3 is about 3 nm, the thickness T1 of the first optical layer 330 of the first and second organic light emitting devices OLED1 and OLED2 can be greater than 0 nm and less than or equal to 12 nm.

In addition, the first optical layer 330 of the first to third organic light emitting devices OLED1 to OLED3 can include the same material. For example, the first optical layer 330 can include the same material as the first hole injection layer 310 or the first hole transport layer 320. In this instance, the first optical layer 330 can assist holes provided from the first electrode 200 to be easily injected or transported to the first light emitting layer 340. Alternatively, the first optical layer 330 can be formed of an electron block layer material. In this instance, the first optical layer 330 can prevent electrons injected into the first light emitting layer 340 from leaking through the first hole injection layer 310 or the first hole transport layer 320, thereby improving the luminous efficiency of the first light emitting layer 340, by improving the coupling of holes and electrons in the first light emitting layer 340.

Because the first optical layers 330 of the first and second organic light emitting devices OLED1 and OLED2 include the same material and have the same or substantially same thickness, the first optical layers 330 of the first and second organic light emitting devices OLED1 and OLED2 can be formed simultaneously. That is, the first optical layer 330 can be formed in common in the first and second sub-pixels SP1 and SP2, and the first and second organic light emitting devices OLED1 and OLED2 can share the first optical layer 330. Accordingly, a process of the organic light emitting device can be simplified.

In the first to third organic light emitting devices OLED1 to OLED3, the first light emitting layer 340 can be disposed on the first optical layer 330. In more detail, the first light emitting layer 340 of the first organic light emitting device OLED1 can generate red light, the first light emitting layer 340 of the second organic light emitting device OLED2 can generate green light, and the first light emitting layer 340 of the third organic light emitting device OLED3 can generate blue light. In addition, to implement micro cavity characteristics, a thickness of the first light emitting layer 340 of the third organic light emitting device OLED3 can be smaller than a thickness of the first light emitting layer 340 of the first and second organic light emitting devices OLED1 and OLED2, but is not limited thereto.

In the first to third organic light emitting devices OLED1 to OLED3, the first electron transport layer 350 is disposed on the first light emitting layer 340 to assist the electrons provided from the charge generation layer 400 to be easily transported to the first light emitting layer 340. Also, the first electron transport layer 350 of the first to third organic light emitting devices OLED1 to OLED3 includes the same material and can be formed with the same or substantially same thickness, but is not limited thereto.

In the first to third organic light emitting devices OLED1 to OLED3, the charge generation layer 400 is disposed on the first electron transport layer 350 and can include an n-type charge generation layer 410 and a p-type charge generation layer 420. Further, the n-type charge generation layer 410 is disposed on the first electron transport layer 350 and can provide electrons to the first stack 300. Also, the n-type charge generation layer 410 of the first to third organic light emitting devices OLED1 to OLED3 includes the same material and can be formed to have the same or substantially same thickness, but is not limited thereto.

In the first to third organic light emitting devices OLED1 to OLED3, the p-type charge generation layer 420 is disposed on the n-type charge generation layer 410 and can provide holes to the second stack 500. Also, the p-type charge generation layer 420 of the first to third organic light emitting devices OLED1 to OLED3 includes the same material and can be formed to have the same or substantially same thickness, but is not limited thereto.

As shown in FIG. 1, in the first to third organic light emitting devices OLED1 to OLED3, the second stack 500 can be disposed on the p-type charge generation layer 420. Also, the second stack 500 of each of the first to third organic light emitting devices OLED1 to OLED3 can include a second hole transport layer 510, a second optical layer 520, a second light emitting layer 530, a hole block layer 540, and a second electron transport layer 550.

Further, in the first to third organic light emitting devices OLED1 to OLED3, the second hole transport layer 510 is disposed on the p-type charge generation layer 420, and assist holes provided from the p-type charge generation layer 420 to be easily transported to the second light emitting layer 530. Also, the second hole transport layer 510 of the first to third organic light emitting devices OLED1 to OLED3 can include the same material each other and can be formed to have the same thickness, but is not limited thereto. In addition, the second hole transport layer 510 can include the same material as the first hole transport layer 320, but is not limited thereto.

Further, in the first to third organic light emitting devices OLED1 to OLED3, the second optical layer 520 can be disposed on the second hole transport layer 510. In this instance, the thicknesses of the second optical layer 520 of the first to third organic light emitting devices OLED1 to OLED3 can be different from each other. In more detail, a thickness T2 of the second optical layer 520 of the first organic light emitting device OLED1 can be about five times or more a thickness T3 of the second optical layer 520 of the second organic light emitting device OLED2. For example, when the thickness T3 of the second optical layer 520 of the second organic light emitting device OLED2 is greater than 0 nm and less than or equal to 12 nm, the thickness T2 of the second optical layer 520 of the first organic light emitting device OLED1 can be greater than or equal to 55 nm and less than or equal to 66 nm.

Also, as the thickness T1 of the first optical layer 330 of the first organic light emitting device OLED1 increases, the thickness T2 of the second optical layer 520 of the first organic light emitting device OLED1 can decrease. As described above, the thickness T1 of the first optical layer 330 of the first organic light emitting device OLED1 can be greater than 0 nm and less than or equal to 12 nm. As the thickness T1 of the first optical layer 330 of the first organic light emitting device OLED1 increases from 0 nm to 12 nm, the thickness T2 of the second optical layer 520 of the first organic light emitting device OLED1 can decrease from 66 nm to 55 nm. Also, the thickness T2 of the second optical layer 520 of the first organic light emitting device OLED1 can be greater than or equal to five times the thickness T1 of the first optical layer 330 of the first organic light emitting device OLED1. Accordingly, by maintaining the sum of the thicknesses T1 and T2 of the first and second optical layers 330 and 520 of the first organic light emitting device OLED1, it is possible to maintain micro cavity characteristics and reduce fluctuations in characteristics of devices.

Likewise, as the thickness T1 of the first optical layer 330 of the second organic light emitting device OLED2 increases, the thickness T3 of the second optical layer 520 of the second organic light emitting device OLED2 can decrease. As described above, the thickness T1 of the first optical layer 330 of the second organic light emitting device OLED2 can be greater than 0 nm and less than or equal to 12 nm. As the thickness T1 of the first optical layer 330 of the second organic light emitting device OLED2 increases from 0 nm to 12 nm, the thickness T3 of the second optical layer 520 of the second organic light emitting device OLED2 can decrease from 12 nm to 0 nm. Accordingly, by maintaining the sum of the thicknesses T1 and T3 of the first and second optical layers 330 and 520 of the second organic light emitting device OLED2, it is possible to maintain micro cavity characteristics and reduce fluctuations in characteristics of devices.

In addition, a thickness Tb of the second optical layer 520 of the third organic light emitting device OLED3 can be about 5 nm. That is, the thickness T1 of the first optical layer 330 of the first and second organic light emitting devices OLED1 and OLED2 can be formed up to three times the thickness Tb of the second optical layers 520 of the third organic light emitting device OLED3.

In the first to third organic light emitting devices OLED1 to OLED3, the second light emitting layer 530 can be disposed on the second optical layer 520. In addition, the second light emitting layer 530 of the first organic light emitting device OLED1 can generate red light, the second light emitting layer 530 of the second organic light emitting device OLED2 can generate green light, and the second light emitting layer 530 of the third organic light emitting device OLED3 can generate blue light. Also, to implement micro cavity characteristics, a thickness of the second light emitting layer 530 of the third organic light emitting device OLED3 can be smaller than a thickness of the second light emitting layer 530 of the first and second organic light emitting devices OLED1 and OLED2, but is not limited thereto.

In the first to third organic light emitting devices OLED1 to OLED3, the hole block layer 540 can be disposed on the second light emitting layer 530. In more detail, the hole block layer 540 prevents or at least reduces holes injected into the second light emitting layer 530 from leaking through the second electron transport layer 550, thereby improving the light emitting efficiency of the second light emitting layer 530 by improving the coupling of holes and electrons in the second light emitting layer 530.

Further, in the first to third organic light emitting devices OLED1 to OLED3, the second electron transport layer 550 is disposed on the hole block layer 540 to assist the electrons provided from the second electrode 600 to be easily transported to the second light emitting layer 530. Also, the second electron transport layer 550 of the first to third organic light emitting devices OLED1 to OLED3 includes the same material each other and can be formed with the same or substantially same thickness, but is not limited thereto.

As shown in FIG. 1, in the first to third organic light emitting devices OLED1 to OLED3, the second electrode 600 is disposed on the second stack 500 and can be disposed in each of the first to third sub-pixels SP1 to SP3. The second electrode 600 can provide electrons to the second stack 500. Because the display device according to the first embodiment of the present invention is configured in the top emission type, the second electrode 600 can include a transparent conductive material such as ITO (IZO) or Indium Zinc Oxide (IZO) to transmit light emitted from the first and second stacks 300 and 500 toward an upper side of the display device.

Therefore, the first embodiment of the present invention discloses a structure in which the first and second organic light emitting devices OLED1 and OLED2 share the first optical layer 330. Also, as the thickness of the first optical layer 330 of the first and second organic light emitting devices OLED1 and OLED2 increases, the thickness of the second optical layers 520 of the first and second organic light emitting devices OLED1 and OLED2 can decrease. Accordingly, because the first and second organic light emitting devices OLED1 and OLED2 share the first optical layer 330, the device characteristics of the organic light emitting device can be maintained while simplifying the process of the organic light emitting device.

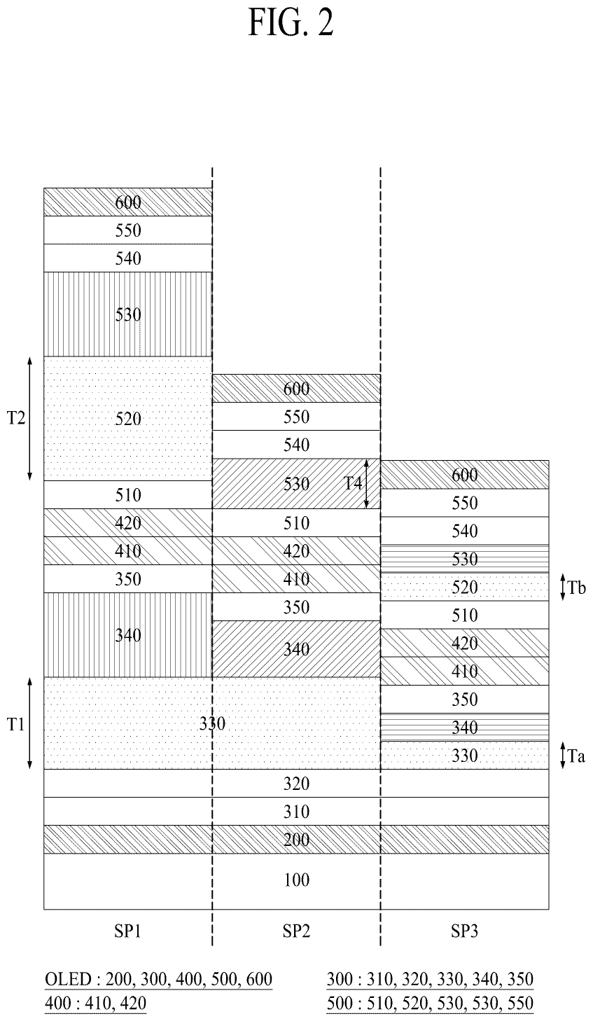

Next, FIG. 2 is a cross-sectional view of a plurality of sub-pixels SP of a display device according to a second embodiment of the present invention. Compared with FIG. 1, substantially the same structure is disclosed except for the structure of the second optical layer 520. Accordingly, the same reference numerals are used for the same components as for the display device illustrated in FIG. 1, and repeated descriptions are omitted.

Compared with the first embodiment of FIG. 1, the second embodiment of FIG. 2 discloses a structure in which the second optical layer 520 of the second organic light emitting device OLED2 is omitted. Accordingly, a thickness of some layers of the first and second stacks 300 and 500 can be changed in the second embodiment of FIG. 2 compared to the first embodiment of FIG. 1.

Referring to FIG. 2, the first optical layers 330 of the first and second organic light emitting devices OLED1 and OLED2 have the same or substantially same thickness and can be commonly formed. In this instance, a thickness range of the first optical layers 330 of the first and second organic light emitting devices OLED1 and OLED2 of FIG. 2 can be wider than that of the first and second organic light emitting devices OLED1 and OLED2 of FIG. 1. Specifically, the thickness T1 of the first optical layer 330 of the first and second organic light emitting devices OLED1 and OLED2 of FIG. 2 can be greater than 0 nm and less than or equal to 32 nm. That is, compared to FIG. 1, the thickness T1 of the first optical layers 330 of the first and second organic light emitting devices OLED1 and OLED2 of FIG. 2 can be greater.

In addition, the thickness T1 of the first optical layer 330 of the first and second organic light emitting devices OLED1 and OLED2 can be formed to be about 11 times the thickness Ta of the first optical layer 330 of the third organic light emitting device OLED3. For example, the thickness Ta of the first optical layer 330 of the third organic light emitting device OLED3 can be about 3 nm. Also, the thickness T1 of the first optical layer 330 of the first and second organic light emitting devices OLED1 and OLED2 can be formed to be about seven times the thickness Tb of the second optical layer 520 of the third organic light emitting device OLED3. For example, the thickness Tb of the first optical layer 330 of the third organic light emitting device OLED3 can be about 5 nm.

In addition, the second optical layer 520 of the first organic light emitting device OLED1 can be disposed on the second hole transport layer 510. In this instance, a thickness range of the first optical layer 330 of the first organic light emitting device OLED1 of FIG. 2 can be wider than that of the first optical layer 330 of the first organic light emitting device OLED1 of FIG. 1. Specifically, the thickness T2 of the second optical layer 520 of the first organic light emitting device OLED1 can be greater than or equal to 34 nm and less than or equal to 66 nm. That is, compared with FIG. 1, the thickness T2 of the second optical layer 520 of the first organic light emitting device OLED1 of FIG. 2 can be smaller. Also, the thickness T2 of the second optical layer 520 of the first organic light emitting device OLED1 can be greater than the thickness T1 of the first optical layer 330 of the first and second organic light emitting devices OLED1 and OLED2.

Because the second organic light emitting device OLED2 does not include the second optical layer 520, the second light emitting layer 530 of the second organic light emitting device OLED2 can be disposed on the second hole transport layer 510. In this instance, the thickness T3 of the second light emitting layer 530 of the second organic light emitting device OLED2 can be greater than or equal to 24.5 nm and less than or equal to 40.5 nm. Also, the thickness of the first light emitting layer 340 of the second organic light emitting device OLED2 can be equal to the thickness T4 of the second light emitting layer 530 of the second organic light emitting device OLED2.

In this instance, because the second optical layer 520 of the first organic light emitting device OLED1 and the second light emitting layer 530 of the second organic light emitting device OLED2 are disposed on the first optical layer 330, as the thickness T1 of the first optical layer 330 of the first and second organic light emitting devices OLED1 and OLED2 increases, the thickness T2 of the second optical layer 520 of the first organic light emitting device OLED1 and the thickness T4 of the second light emitting layer 530 of the second organic light emitting device OLED2 can be reduced. For example, as the thickness T1 of the first optical layer 330 of the first and second organic light emitting devices OLED1 and OLED2 increases from 0 nm to 32 nm, the thickness T2 of the second optical layer 520 of the first organic light emitting device OLED1 can decrease from 66 nm to 34 nm, and the thickness T4 of the second light emitting layer 530 of the second organic light emitting device OLED2 can decrease from 40.5 nm to 24.5 nm.

In conclusion, compared to FIG. 1, FIG. 2 can maintain the characteristics of the device by adjusting the thickness T1 of the first optical layer 330 of the first and second organic light emitting devices OLED1 and OLED2, the thickness T2 of the second optical layer 520 of the first organic light emitting device OLED1, and the thickness T4 of the second light emitting layer 530 of the second organic light emitting device OLED2.

Therefore, even if the second optical layer 520 is omitted from the second organic light emitting device OLED2, the characteristics of the device can be maintained by adjusting the thicknesses of some layers constituting the first and second stacks 300 and 500. Also, because the process of forming the second optical layer 520 in the second organic light emitting device OLED2 can be omitted, the process of the organic light emitting device can be further simplified.

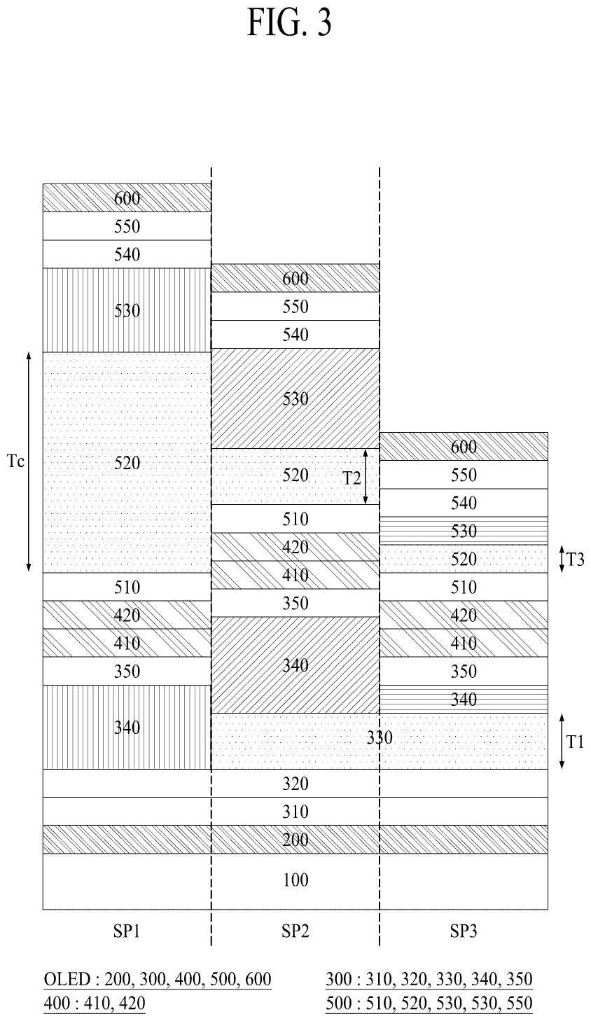

Next, FIG. 3 is a cross-sectional view of a plurality of sub-pixels SP of a display device according to a third embodiment of the present invention. Compared with FIG. 1, substantially the same structure is disclosed except for the structures of the first and second optical layers 330 and 520. Accordingly, the same reference numerals are used for the same components as for the display device shown in FIG. 1, and repeated descriptions are omitted.

The first embodiment of FIG. 1 discloses that the first and second organic light emitting devices OLED1 and OLED2 share the first optical layer 330, but the third embodiment of FIG. 3 discloses that the second and third organic light emitting devices OLED2 and OLED3 share the first optical layer 330. Referring to FIG. 3, the first optical layers 330 of the second and third organic light emitting devices OLED2 and OLED3 have the same or substantially same thickness and can be commonly formed. Further, the thickness T1 of the first optical layer 330 of the second and third organic light emitting devices OLED2 and OLED3 can be greater than or equal to 1 nm and less than or equal to 6 nm. Also, the first organic light emitting device OLED1 may not include the first optical layer 330.

In addition, the thickness Tc of the second optical layer 520 of the first organic light emitting device OLED1 can be greater than 60 nm and less than or equal to 66 nm, the thickness T2 of the second optical layer 520 of the second organic light emitting device OLED2 can be greater than or equal to 6 nm and less than or equal to 11 nm, and the thickness T3 of the second optical layer 520 of the third organic light emitting device OLED3 can be greater than or equal to 2 nm and less than or equal to 7 nm. That is, the thicknesses T2 and T3 of the second optical layers 520 of the second and third organic light emitting devices OLED2 and OLED3 including the first optical layer 330 in common can be less than the thickness Tc of the second optical layer 520 of the first organic light emitting device OLED1. Also, the thickness T1 of the first optical layer 330 of the second and third organic light emitting devices OLED2 and OLED3 can be less than the thickness T2 of the second optical layer 520 of the second organic light emitting device OLED2.

In this instance, as the thickness T1 of the first optical layer 330 of the second and third organic light emitting elements OLED2 and OLED3 increases, the thickness T2 and T3 of the second optical layer 520 disposed on the first optical layer 330 can decrease in the second and third organic light emitting devices OLED2 and OLED3. For example, as the thickness T1 of the first optical layer 330 of the second and third organic light emitting devices OLED2 and OLED3 increases from 1 nm to 6 nm, the thickness T2 of the second optical layer 520 of the second organic light emitting device OLED2 can decrease from 11 nm to 6 nm, and the thickness T3 of the second optical layer 520 of the third organic light emitting device OLED3 can decrease from 7 nm to 2 nm. Also, compared to FIG. 1, the thicknesses of the first optical layer 330 and the second optical layer 520 of FIG. 3 can be smaller.

In conclusion, referring to FIGS. 1 and 3, the first optical layer 330 can be formed to be shared in at least two sub-pixels selectively among the first to third sub-pixels SP1 to SP3. Accordingly, by adjusting the thicknesses of the first optical layer 330 and the second optical layer 520, the process of the organic light emitting device can be simplified and the device characteristics of the organic light emitting device can be maintained. Also, the first and third organic light emitting devices OLED1 and OELD3 can share the first optical layer 330.

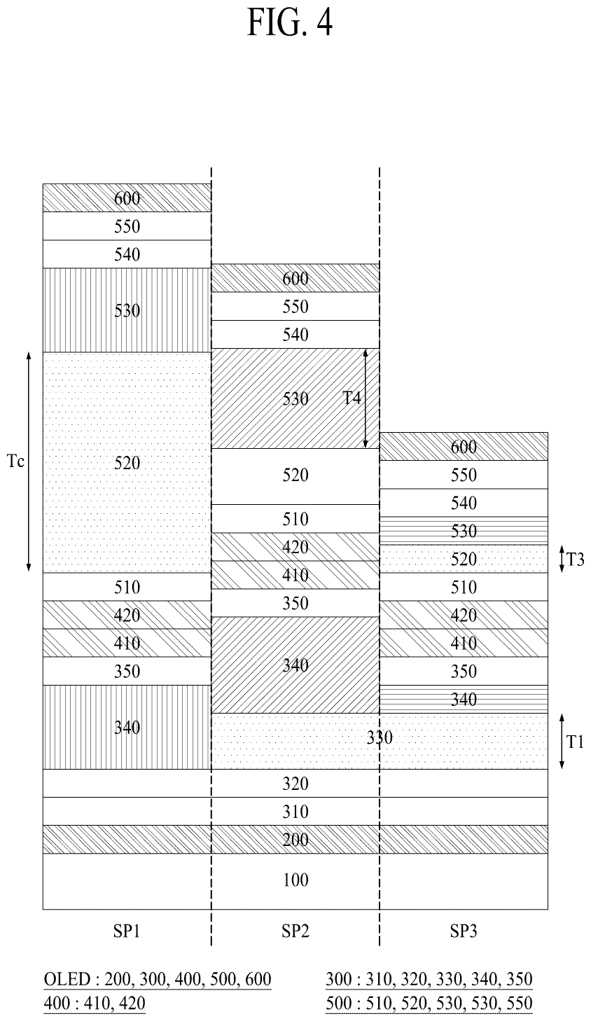

Next, FIG. 4 is a cross-sectional view of a plurality of sub-pixels SP of a display device according to a fourth embodiment of the present invention. Compared with FIG. 3, substantially the same structure is disclosed except for the structure of the second optical layer 520. Accordingly, the same reference numerals are used for the same components as for the display device illustrated in FIG. 3, and repeated descriptions are omitted.

Compared with the third embodiment of FIG. 3, the fourth embodiment of FIG. 4 discloses a structure in which the second optical layer 520 is omitted from the second organic light emitting device OLED2. Accordingly, the thickness of some layers of the first and second stacks 300 and 500 can be changed in the fourth embodiment of FIG. 4 compared to the third embodiment of FIG. 3.

Referring to FIG. 4, the first optical layers 330 of the second and third organic light emitting devices OLED2 and OLED3 have the same or substantially same thickness and can be commonly formed. The thickness T1 of the first optical layer 330 of the second and third organic light emitting devices OLED2 and OLED3 can be greater than or equal to 1 nm and less than or equal to 7 nm.

A ratio of the thickness T1 of the first optical layer 330 of the second and third organic light emitting devices OLED2 and OLED3 to the thickness T3 of the second optical layer 520 of the third organic light emitting device OLED3 can be 1:7 to 7:1. For example, as the thickness T1 of the first optical layer 330 of the second and third organic light emitting devices OLED2 and OLED3 increases from 1 nm to 7 nm, the thickness T3 of the second optical layer 520 of the third organic light emitting device OLED3 can decrease from 7 nm to 1 nm.

In addition, the thickness Tc of the second optical layer 520 of the first organic light emitting device OLED1 can be greater than 60 nm and less than or equal to 66 nm. That is, the thickness Tc of the second optical layer 520 of the first organic light emitting device OLED1 can be about 10 times the thickness T1 of the first optical layer 330 of the second and third organic light emitting devices OLED2 and OLED3 or about 10 times the thickness T3 of the second optical layer 520 of the third organic light emitting device OLED3.

Because the second organic light emitting device OLED2 does not include the second optical layer 520, the second light emitting layer 530 of the second organic light emitting device OLED2 can be disposed on the second hole transport layer 510. In this instance, the thickness T4 of the second light emitting layer 530 of the second organic light emitting device OLED2 can be greater than or equal to 37 nm and less than or equal to 40 nm. Also, the thickness of the first light emitting layer 340 of the second organic light emitting device OLED2 can be equal to the thickness T4 of the second light emitting layer 530 of the second organic light emitting device OLED2.

In this instance, because the second optical layer 520 of the third organic light emitting device OLED3 and the second light emitting layer 530 of the second organic light emitting device OLED2 are disposed on the first optical layer 330, as the thickness T1 of the first optical layer 330 of the second and third organic light emitting devices OLED2 and OLED3 increases, the thickness T3 of the second optical layer 520 of the third organic light emitting device OLED3 and the thickness T4 of the second light emitting layer 530 of the second organic light emitting device OLED2 can be reduced. For example, as the thickness T1 of the first optical layer 330 of the second and third organic light emitting devices OLED2 and OLED3 increases from 1 nm to 7 nm, the thickness T3 of the second optical layer 520 of the third organic light emitting device OLED3 can decrease from 7 nm to 1 nm, and the thickness T4 of the second light emitting layer 530 of the second organic light emitting device OLED2 can decrease from 40 nm to 37 nm.

In conclusion, compared to FIG. 3, even if the second optical layer 520 is omitted from the second organic light emitting device OLED2, FIG. 4 can maintain the characteristics of the device by adjusting the thickness T1 of the first optical layer 330 of the second and third organic light emitting devices OLED2 and OLED3, the thickness T3 of the second optical layer 520 of the third organic light emitting device OLED3, and the thickness T4 of the second light emitting layer 530 of the second organic light emitting device OLED2.

Therefore, even if the second optical layer 520 is omitted from the second organic light emitting device OLED2, the characteristics of the device can be maintained by adjusting the thicknesses of some layers constituting the first and second stacks 300 and 500. Also, because the process of forming the second optical layer 520 in the second organic light emitting device OLED2 can be omitted, the process of the organic light emitting device can be further simplified.

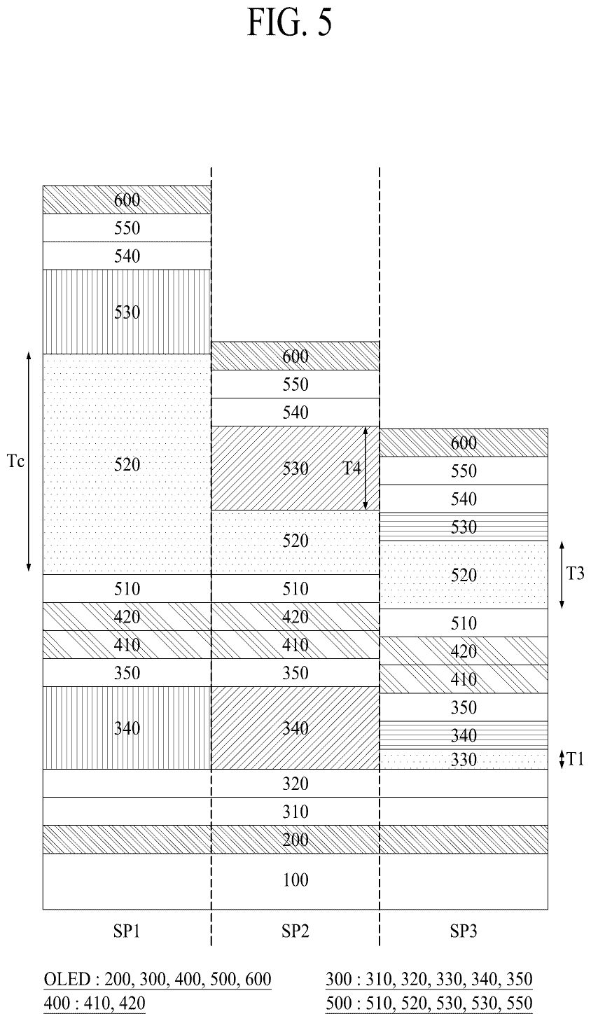

Next, FIG. 5 is a cross-sectional view of a plurality of sub-pixels SP of a display device according to a fifth embodiment of the present invention. Compared with FIG. 4, substantially the same structure is disclosed except for the structures of the first and second optical layers 330 and 520. Accordingly, the same reference numerals are used for the same components as for the display device shown in FIG. 4, and repeated descriptions are omitted.

Compared with the fourth embodiment of FIG. 4, the fifth embodiment of FIG. 5 discloses a structure in which the second and third organic light emitting devices OLED2 and OLED3 share the second optical layer 520. Accordingly, compared to the fourth embodiment of FIG. 4, the thickness of some layers of the first and second stacks 300 and 500 can be changed in the fifth embodiment of FIG. 5.

Referring to FIG. 5, the second optical layers 520 of the second and third organic light emitting devices OLED2 and OLED3 have the same or substantially same thickness and can be commonly formed. The thickness T1 of the second optical layer 520 of the second and third organic light emitting devices OLED2 and OLED3 can be greater than or equal to 1 nm and less than or equal to 6 nm.

A ratio of the thickness T1 of the second optical layer 520 of the second and third organic light emitting devices OLED2 and OLED3 to the thickness T3 of the first optical layer 330 of the third organic light emitting device OLED3 can be 1:7 to 7:1. For example, as the thickness T1 of the second optical layer 520 of the second and third organic light emitting devices OLED2 and OLED3 increases from 1 nm to 6 nm, the thickness T3 of the first optical layer 330 of the third organic light emitting device OLED3 can decrease from 7 nm to 2 nm.

In addition, the thickness Tc of the second optical layer 520 of the first organic light emitting device OLED1 can be greater than 60 nm and less than or equal to 66 nm. That is, the thickness Tc of the second optical layer 520 of the first organic light emitting device OLED1 can be about 10 times the thickness T1 of the second optical layer 520 of the second and third organic light emitting devices OLED2 and OLED3 or about 10 times the thickness T3 of the first optical layer 330 of the third organic light emitting device OLED3.

Compared to the disclosure of the structure in which the second organic light emitting device OLED2 of FIG. 4 does not include the second optical layer 520, the second organic light emitting device OLED2 of FIG. 5 does not include the first optical layer 330. Because the second organic light emitting device OLED2 does not include the first optical layer 330, the first light emitting layer 340 of the second organic light emitting device OLED2 can be disposed on the first hole transport layer 320. In this instance, the thickness T4 of the first light emitting layer 340 of the second organic light emitting device OLED2 can be greater than or equal to 37.5 nm and less than or equal to 40 nm. Also, the thickness of the second light emitting layer 530 of the second organic light emitting device OLED2 can be equal to the thickness T4 of the first light emitting layer 340 of the second organic light emitting device OLED2.

In this instance, as the thickness T1 of the second optical layer 520 of the second and third organic light emitting devices OLED2 and OLED3 increases, the thickness T3 of the first optical layer 330 of the third organic light emitting device OLED3 and the thickness T4 of the first light emitting layer 340 of the second organic light emitting device OLED2 can decrease. For example, as the thickness T1 of the second optical layer 520 of the second and third organic light emitting devices OLED2 and OLED3 increases from 1 nm to 6 nm, the thickness T3 of the first optical layer 330 of the third organic light emitting device OLED3 can decrease from 7 nm to 2 nm, and the thickness T4 of the first light emitting layer 340 of the second organic light emitting device OLED2 can decrease from 40 nm to 37.5 nm.

In conclusion, FIG. 5 discloses a structure in which the second and third organic light emitting devices OLED2 and OLED3 share the second optical layer 520 rather than the first optical layer 330. That is, a structure in which any one of the first and second optical layers 330 and 520 is commonly formed in the second and third organic light emitting devices OLED2 and OLED3 can be disclosed. Also, the first and second organic light emitting devices OLED1 and OLED2 or the first and third organic light emitting devices OLED1 and OELD3 can share the second optical layer 520 with each other.

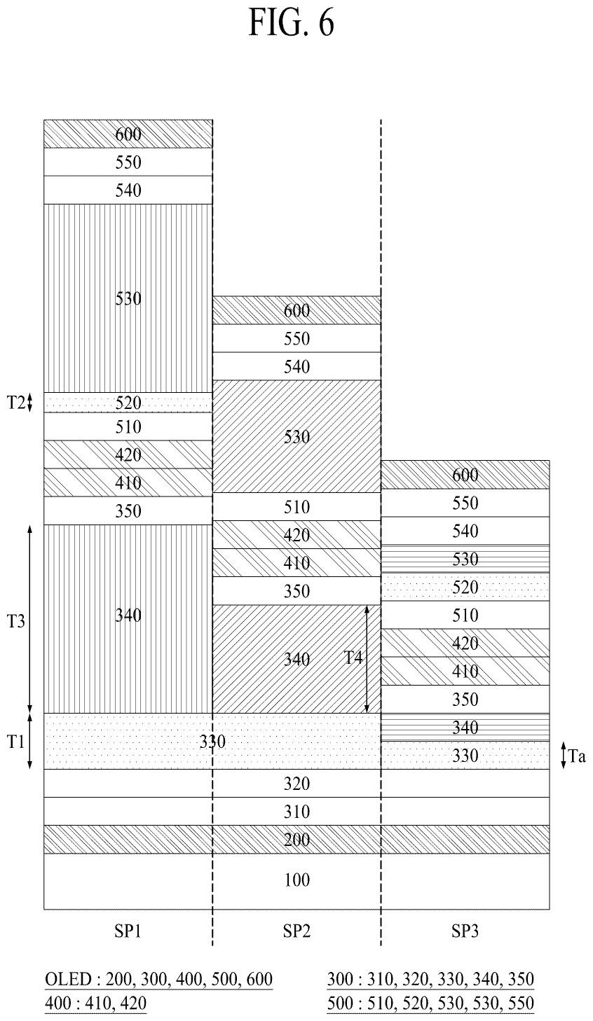

Next, FIG. 6 is a cross-sectional view of a plurality of sub-pixels SP of a display device according to a sixth embodiment of the present invention. FIGS. 1 to 5 disclose a structure in which only one optical layer of the first and second optical layers 330 and 520 is commonly formed, whereas the sixth embodiment of FIG. 6 discloses a structure in which each of the first and second optical layers 330 and 520 is commonly formed.

Referring to FIG. 6, the first optical layers 330 of the first and second organic light emitting devices OLED1 and OLED2 are commonly formed, and the second optical layers 520 of the first and third organic light emitting devices OLED1 and OLED3 can be commonly formed.

In addition, the thickness T1 of the first optical layer 330 of the first and second organic light emitting devices OLED1 and OLED2 can be greater than or equal to 1 nm and less than or equal to 8 nm. Also, the thickness Ta of the first optical layer 330 of the third organic light emitting device OLED3 can be about 3 nm. That is, the thickness T1 of the first optical layer 330 of the first and second organic light emitting devices OLED1 and OLED2 can be about three times or less the thickness Ta of the first optical layer 330 of the third organic light emitting device OLED3.

Further, the thickness T2 of the second optical layer 530 of the first and third organic light emitting devices OLED1 and OLED3 can be about 5 nm. That is, the thickness T1 of the first optical layer 330 of the first and second organic light emitting devices OLED1 and OLED2 can be about twice or less the thickness T2 of the second optical layer 530 of the first and third organic light emitting devices OLED1 and OLED3. Also, the second organic light emitting device OLED2 can not include the second optical layer 530.

In addition, the thickness T3 of the first light emitting layer 340 of the first organic light emitting device OLED1 can be greater than or equal to 62.5 nm and less than or equal to 66 nm, and the thickness T4 of the first light emitting layer 340 of the second organic light emitting device OLED2 can be greater than or equal to 36.5 nm and less than or equal to 40 nm. That is, the thickness T3 of the first light emitting layer 340 of the first organic light emitting device OLED1 can be greater than the thickness T4 of the first light emitting layer 340 of the second organic light emitting device OLED2. Also, the thickness of the second light emitting layer 530 of the first organic light emitting device OLED1 can be equal to the thickness T3 of the first light emitting layer 340 of the first organic light emitting device OLED1. Further, the thickness of the second light emitting layer 530 of the second organic light emitting device OLED2 can be equal to the thickness T4 of the first light emitting layer 340 of the second organic light emitting device OLED2.

In this instance, as the thickness T1 of the first optical layer 330 of the first and second organic light emitting devices OLED1 and OLED2 increases, the thickness T3 and T4 of the first light emitting layer 340 disposed on the first optical layer 330 can decrease in the first and second organic light emitting devices OLED1 and OLED2. For example, as the thickness T1 of the first optical layer 330 of the first and second organic light emitting devices OLED1 and OLED2 increases from 1 nm to 8 nm, the thickness T3 of the first light emitting layer 340 of the first organic light emitting device OLED1 can decrease from 66 nm to 62.5 nm, and the thickness T4 of the first light emitting layer 340 of the second organic light emitting device OLED2 can decrease from 40 nm to 36.5 nm.

In conclusion, FIG. 6 discloses forming the first optical layers 330 of the first and second organic light emitting devices OLED1 and OLED2 in common and forming the second optical layers 520 of the first and third organic light emitting devices OLED1 and OLED3 in common. That is, the first organic light emitting device OLED1 can share both the first and second optical layers 330 and 520, and the second and third organic light emitting devices OLED2 and OLED3 can share any one of the first and second optical layers 330 and 520. Accordingly, compared to a structure of sharing one optical layer, a process of forming the first and second optical layers 330 and 520 can be further simplified.

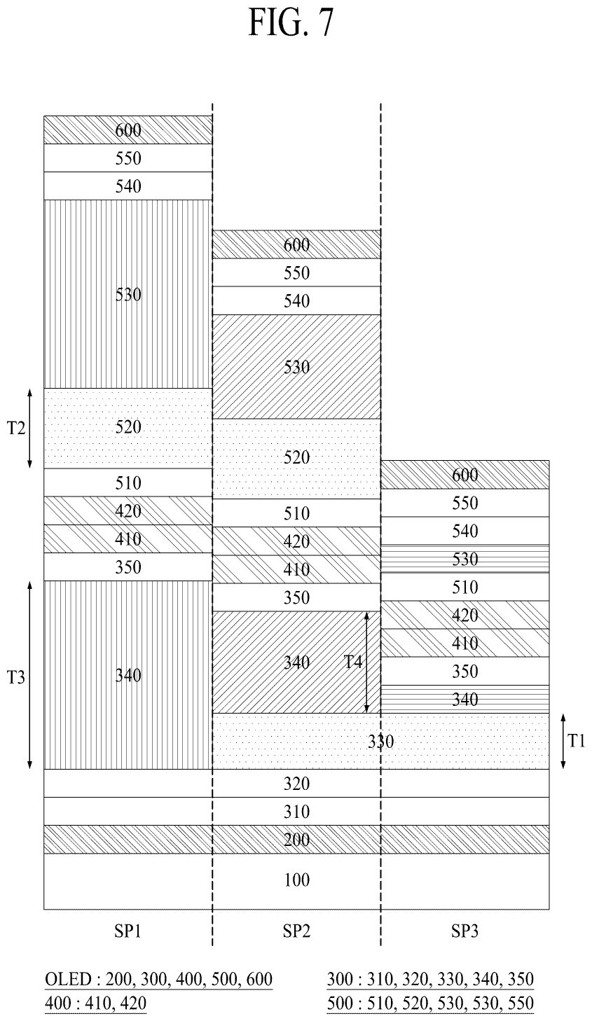

Next, FIG. 7 is a cross-sectional view of a plurality of sub-pixels SP of a display device according to a seventh embodiment of the present invention. The sixth embodiment of FIG. 6 discloses a structure in which the first organic light emitting device OLED1 shares both the first and second optical layers 330 and 520, but the seventh embodiment of FIG. 7 discloses a structure in which the second organic light emitting device OLED2 shares both the first and second optical layers 330 and 520.

Referring to FIG. 7, the first optical layers 330 of the second and third organic light emitting devices OLED2 and OLED3 can be formed in common, and the second optical layers 520 of the first and second organic light emitting devices OLED1 and OLED2 can be formed in common. In addition, the thickness T1 of the first optical layer 330 of the second and third organic light emitting devices OLED2 and OLED3 can be about 8 nm. Also, the first organic light emitting device OLED1 may not include the first optical layer 330.

In addition, the thickness T2 of the second optical layer 530 of the first and second organic light emitting devices OLED2 and OLED3 can be equal to or greater than 4 nm and equal to or less than 20 nm. That is, the thickness T2 of the second optical layer 530 of the first and second organic light emitting devices OLED2 and OLED3 can be equal to or greater than 0.5 times and equal to or less than three times the thickness T1 of the first optical layer 330 of the first and second organic light emitting devices OLED2 and OLED3. Also, the third organic light emitting device OLED3 cannot include the second optical layer 530.

Further, the thickness T3 of the first light emitting layer 340 of the first organic light emitting device OLED1 can be greater than or equal to 59 nm and less than or equal to 67 nm, and the thickness T4 of the first light emitting layer 340 of the second organic light emitting device OLED2 can be greater than or equal to 26.5 nm and less than or equal to 34.5 nm. That is, the thickness T3 of the first light emitting layer 340 of the first organic light emitting device OLED1 can be greater than the thickness T4 of the first light emitting layer 340 of the first organic light emitting device OLED1. Furthermore, the thickness of the second light emitting layer 530 of the first organic light emitting device OLED1 can be equal to the thickness T3 of the first light emitting layer 340 of the first organic light emitting device OLED1. The thickness of the second light emitting layer 530 of the second organic light emitting device OLED2 can also be equal to the thickness T4 of the first light emitting layer 340 of the second organic light emitting device OLED2. Also, the thickness T2 of the second optical layer 530 of the second and third organic light emitting devices OLED2 and OLED3 can be less than the thickness T4 of the first light emitting layer 340 of the second organic light emitting device OLED2.

In this instance, as the thickness T1 of the first optical layer 330 of the second and third organic light emitting devices OLED2 and OLED3 increases, the thickness T3 and T4 of the first light emitting layer 340 disposed on the first optical layer 330 can decrease in the first and second organic light emitting devices OLED1 and OLED2. For example, as the thickness T1 of the second optical layer 520 of the second and third organic light emitting devices OLED2 and OLED3 increases from 4 nm to 20 nm, the thickness T3 of the first light emitting layer 340 of the first organic light emitting device OLED1 can decrease from 67 nm to 59 nm, and the thickness T4 of the first light emitting layer 340 of the second organic light emitting device OLED2 can decrease from 34.5 nm to 26.5 nm.

In conclusion, FIG. 7 discloses forming the first optical layers 330 of the second and third organic light emitting devices OLED2 and OLED3 in common and forming the second optical layers 520 of the first and second organic light emitting devices OLED1 and OLED2 in common. That is, the second organic light emitting device OLED2 can share both the first and second optical layers 330 and 520, and the first and third organic light emitting devices OLED2 and OLED3 can share any one of the first and second optical layers 330 and 520. Accordingly, compared to a structure of sharing one optical layer, the process of forming the first and second optical layers 330 and 520 can be further simplified.

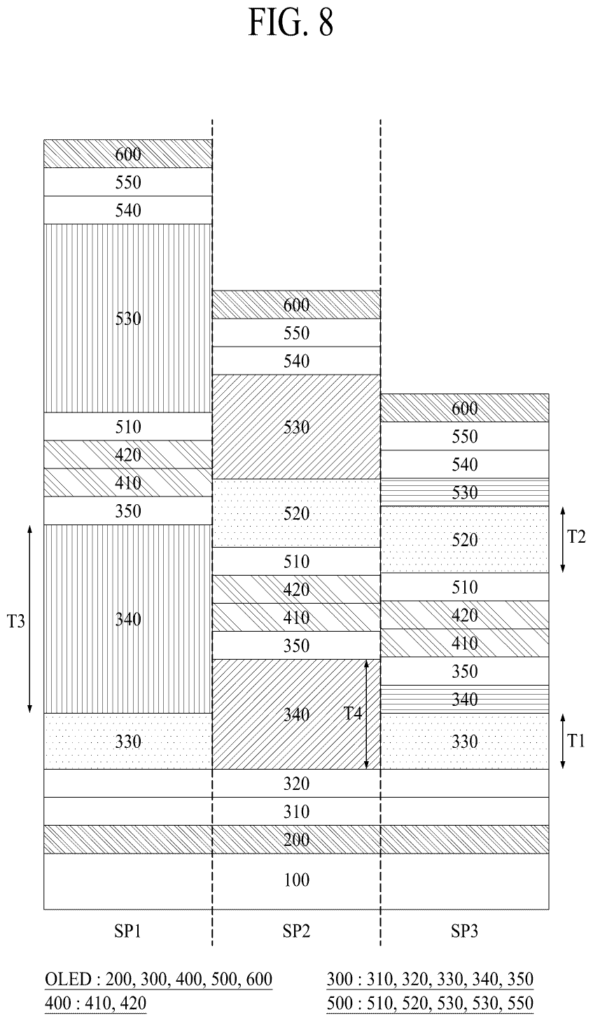

Next, FIG. 8 is a cross-sectional view of a plurality of sub-pixels SP of a display device according to an eighth embodiment of the present invention. The sixth embodiment of FIG. 6 discloses a structure in which the first organic light emitting device OLED1 shares both the first and second optical layers 330 and 520, but the eighth embodiment of FIG. 8 discloses a structure in which the third organic light emitting device OLED3 shares both the first and second optical layers 330 and 520.

Referring to FIG. 8, the first optical layers 330 of the first and third organic light emitting devices OLED1 and OLED3 can be formed in common, and the second optical layers 520 of the second and third organic light emitting devices OLED2 and OLED3 can be formed in common. The thickness T1 of the first optical layer 330 of the first and third organic light emitting devices OLED2 and OLED3 can be greater than or equal to 2 nm and less than or equal to 6 nm. Also, the second organic light emitting device OLED2 may not include the first optical layer 330.

In addition, the thickness T2 of the second optical layer 530 of the second and third organic light emitting devices OLED2 and OLED3 can be greater than or equal to 2 nm and less than or equal to 6 nm. The sum of the thickness T1 of the first optical layer 330 of the first and third organic light emitting devices OLED2 and OLED3 and the thickness T2 of the second optical layer 530 of the second and third organic light emitting devices OLED2 and OLED3 can be 10 nm or less. That is, as the thickness T1 of the first optical layer 330 of the first and third organic light emitting devices OLED2 and OLED3 increases from 2 nm to 6 nm, the thickness T2 of the second optical layer 530 of the second and third organic light emitting devices OLED2 and OLED3 can decrease from 6 nm to 2 nm. Also, the first organic light emitting device OLED3 may not include the second optical layer 530.

In addition, the thickness T3 of the first light emitting layer 340 of the first organic light emitting device OLED1 can be greater than or equal to 66 nm and less than or equal to 68 nm, and the thickness T4 of the first light emitting layer 340 of the second organic light emitting device OLED2 can be greater than or equal to 37.5 nm and less than or equal to 39.5 nm. That is, the thickness T3 of the first light emitting layer 340 of the first organic light emitting device OLED1 can be greater than the thickness T4 of the first light emitting layer 340 of the first organic light emitting device OLED1. In addition, the thickness of the second light emitting layer 530 of the first organic light emitting device OLED1 can be equal to the thickness T3 of the first light emitting layer 340 of the first organic light emitting device OLED1, and the thickness of the second light emitting layer 530 of the second organic light emitting device OLED2 can be equal to the thickness T4 of the first light emitting layer 340 of the second organic light emitting device OLED2.

In this instance, as the thickness T1 of the first optical layer 330 of the first and third organic light emitting devices OLED1 and OLED3 increases, the thickness T3 of the first light emitting layer 340 of the first organic light emitting device OLED1 can decrease and the thickness T4 of the first light emitting layer 340 of the second organic light emitting device OLED2 can increase. For example, as the thickness T1 of the first optical layer 330 of the first and third organic light emitting devices OLED1 and OLED3 increases from 2 nm to 6 nm, the thickness T3 of the first light emitting layer 340 of the first organic light emitting device OLED1 can decrease from 68 nm to 66 nm, and the thickness T4 of the first light emitting layer 340 of the second organic light emitting device OLED2 can increase from 37.5 nm to 39.5 nm.

In conclusion, FIG. 8 discloses forming the first optical layers 330 of the first and third organic light emitting devices OLED1 and OLED3 in common and forming the second optical layers 520 of the second and third organic light emitting devices OLED2 and OLED3 in common. That is, the third organic light emitting device OLED3 can share both the first and second optical layers 330 and 520, and the first and second organic light emitting devices OLED1 and OLED2 can share any one of the first and second optical layers 330 and 520. Accordingly, compared to a structure of sharing one optical layer, the process of forming the first and second optical layers 330 and 520 can be further simplified.

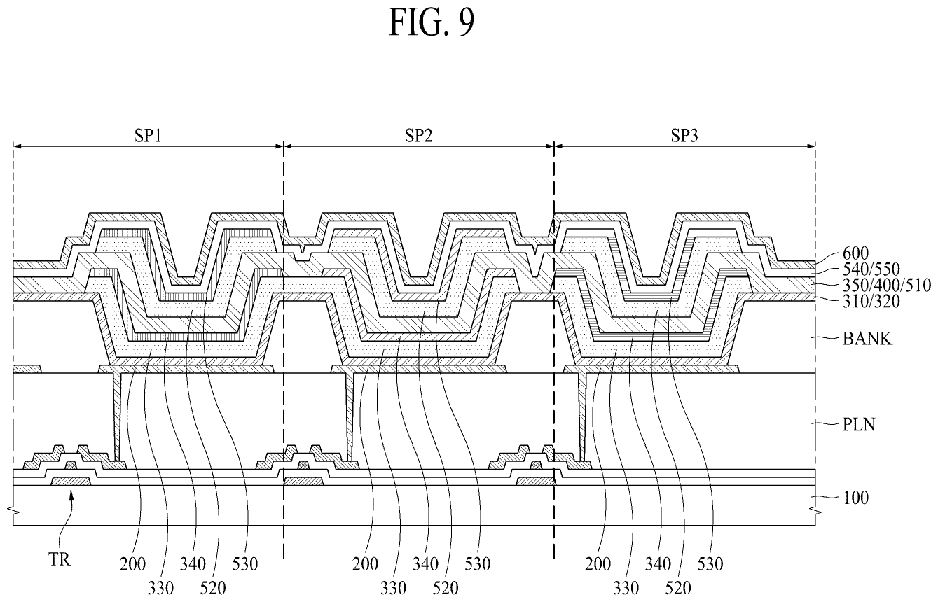

Next, FIG. 9 is another cross-sectional view of a display device according to a first embodiment of the present invention. Compared with FIG. 1, FIG. 9 specifically shows structures other than organic light emitting device OLED. Referring to FIG. 9, a display device according to a first embodiment of the present invention can include a substrate 100, a thin film transistor TR, a planarization layer PLN, a bank, and first to third light emitting devices OLED1-OLED3. The substrate 100 can be made of a transparent insulating material such as glass, but is not limited thereto.

In addition, the thin film transistor TR is disposed on the substrate 100 and can be disposed in each of the first to third sub-pixels SP1 to SP3. The thin film transistor TR can include a semiconductor layer, a gate electrode, a source electrode and a drain electrode. Also, the thin film transistor TR can disclose a bottom gate structure in which the semiconductor layer is disposed on the gate electrode or a top gate structure in which the gate electrode is disposed on the semiconductor layer.

Further, the planarization layer PLN can be disposed on the thin film transistor TR to compensate for a step difference caused by the thin film transistor TR. The planarization layer PLN can also be formed of an organic insulating material such as an acrylic resin, an epoxy resin, a phenolic resin, a polyamide resin, or a polyimide resin.

In addition, the first to third light emitting devices OLED can be disposed on the planarization layer PLN. As described above in FIG. 1, each of the first to third light emitting devices OLED can include a first electrode 200, a first stack 300, a charge generation layer 400, a second stack 500, and a second electrode 600. Further, the first electrode 200 can be disposed on the planarization layer PLN and can function as an anode of the display device. As shown in FIG. 9, the first electrode 200 can be electrically connected with the drain electrode of the thin film transistor TR through a contact hole formed in the planarization layer PLN.

In addition, the bank can be disposed on the planarization layer PLN and the first electrode 200. In particular, the bank defines an emitting area and a non-emitting area. That is, a region in which the bank is not disposed can be the emitting area, and a region in which the bank is disposed can be the non-emitting area. The bank can also include an organic insulating material such as an acrylic resin, an epoxy resin, a phenolic resin, a polyamide resin, a polyimide resin, etc. Alternatively, the bank can include an inorganic insulating material such as silicon oxide (SiOx), silicon nitride (SiNx), silicon oxynitride (SiOxNy), etc. Also, the bank can include a black dye in order to absorb light incident from the outside.

In addition, the first stack 300 can be disposed on the first electrode 200 and can also be disposed on the bank. As described above in FIG. 1, the first stack 300 can include a first hole injection layer 310, a first hole transport layer 320, a first optical layer 330, a first light emitting layer 340, and a first electron transport layer 350. Also, the first hole injection layer 310 and the first hole transport layer 320 can be commonly formed in the first to third sub-pixels SP1-SP3. Accordingly, the first hole injection layer 310 and the first hole transport layer 320 can be cover the bank BANK between the first and second sub-pixels SP1 and SP2 and the bank BANK between the second and third sub-pixels SP2 and SP3.

As described above in FIG. 1, the first optical layer 330 can be formed in common in the first and second sub-pixels SP1 and SP2. Accordingly, the first optical layer 330 of the first sub-pixel SP1 can be extend to the second sub-pixel SP2. That is, the first optical layers 330 of the first and second sub-pixels SP1 and SP2 are formed in common, and the first and second sub-pixels SP1 and SP2 can share the first optical layer 330. Also, the first optical layer 330 of the first and second sub-pixels SP1 and SP2 can be cover an entire surface of the bank BANK between the first and second sub-pixels SP1 and SP2.

In addition, the first optical layer 330 disposed in the third sub-pixel SP3 can be spaced apart from the first optical layer 330 of the first and second sub-pixels SP1 and SP2. Accordingly, the first optical layer 330 of the third sub-pixel SP3 can be disposed in the area surrounded by the bank, or can cover a part of an upper surface of the bank. That is, on the upper surface of the bank BANK between the second and third sub-pixels SP2 and SP3, the first optical layer 330 of the first and second sub-pixels SP1 and SP2 and the first optical layer 330 of the third sub-pixel SP3 can be spaced apart from each other. The first light emitting layer 340 can be disposed in the first to third sub-pixels SP1 to SP3, respectively.

In addition, the first electron transport layer 350 and the charge generation layer 400 can be commonly formed in the first to third sub-pixels SP1 to SP3. Accordingly, the first electron transport layer 350 and the charge generation layer 400 can cover the bank BANK between the first and second sub-pixels SP1 and SP2 and the bank BANK between the second and third sub-pixels SP2 and SP3.

As described above in FIG. 1, the second stack 500 can include a second hole transport layer 510, a second optical layer 520, a second light emitting layer 530, a hole block layer 540, and a second electron transport layer 550. The second hole transport layer 510, the hole block layer 540, and the second electron transport layer 550 can be commonly formed in the first to third sub-pixels SP1 to SP3. Also, the second optical layer 520 and the second light emitting layer 530 can be disposed in the first to third sub-pixels SP1 to SP3, respectively.

In conclusion, because the first optical layer 330 can be formed in common in the first and second sub-pixels SP1 and SP2, the process can be simplified compared to forming the first optical layer 330 in each of the first and second sub-pixels SP1 and SP2. According to the present disclosure, the following advantageous effects can be obtained.

According to the present disclosure, the plurality of light conversion layers can be formed so that light efficiency can be improved, and reflectance due to external light can be reduced.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a substrate including a first sub-pixel, a second sub-pixel and a third sub-pixel;
a first light emitting device disposed in the first sub-pixel;
a second light emitting device disposed in the second sub-pixel; and
a third light emitting device disposed in the third sub-pixel,
wherein each of the first light emitting device, the second light emitting device and the third light emitting device includes a first electrode disposed on the substrate, a first hole transport layer disposed on the first electrode, and a first light emitting layer disposed on the first hole transport layer,
wherein each of the first and second light emitting devices includes a first optical layer disposed between the first hole transport layer and the first light emitting layer, and
wherein a thickness of the first optical layer of the first light emitting device is the same as a thickness of the first optical layer of the second light emitting device.

2. The display device of claim 1, wherein the first optical layer of the first light emitting device contacts a lower surface of the first light emitting layer of the first light emitting device.

3. The display device of claim 1, wherein the third light emitting device includes a first optical layer disposed between the first hole transport layer and the first light emitting layer, and
wherein a thickness of the first optical layer of the third light emitting device is different from the thickness of the first optical layer of the first light emitting device and also different from the thickness of the first optical layer of the second light emitting device.

4. The display device of claim 1, wherein the first hole transport layer of the third light emitting device contacts the first light emitting layer of the third light emitting device.

5. The display device of claim 1, wherein each of the first light emitting device, the second light emitting device and the third light emitting device includes a charge generation layer disposed on the first light emitting layer, a second hole transport layer disposed on the charge generation layer, a second optical layer disposed on the second hole transport layer, and a second light emitting layer disposed on the second optical layer, and
wherein a thickness of the second optical layer of the first light emitting device, a thickness of the second optical layer of the second light emitting device, and a thickness of the second optical layer of the third light emitting device are different from each other.

6. The display device of claim 5, wherein the thickness of the second optical layer of the first light emitting device is greater than the thickness of the second optical layer of the second light emitting device.

7. The display device of claim 5, wherein the thickness of the second optical layer of the third light emitting device is smaller than the thickness of the second optical layer of the first light emitting device and also smaller than the thickness of the second optical layer of the second light emitting device.

8. The display device of claim 5, wherein the thickness of the second optical layer of the third light emitting device is greater than the thickness of the second optical layers of the first and second light emitting devices.

9. The display device of claim 5, wherein the thickness of the second optical layer of the first light emitting device is different from the thickness of the first optical layer of the first light emitting device.

10. The display device of claim 1, wherein each of the first light emitting device, the second light emitting device and the third light emitting device includes a charge generation layer disposed on the first light emitting layer, a second hole transport layer disposed on the charge generation layer, and a second light emitting layer disposed on the second hole transport layer,
wherein the first and third light emitting devices include a second optical layer disposed between the second hole transport layer and the second light emitting layer, and
wherein the second optical layers of the first and third light emitting devices have different thicknesses.

11. The display device of claim 10, wherein the second hole transport layer of the second light emitting device contacts the second light emitting layer of the second light emitting device.

12. The display device of claim 10, wherein the thickness of the second optical layer of the first light emitting device is different from the thickness of the first optical layer of the first light emitting device.

13. The display device of claim 1, wherein each of the first light emitting device, the second light emitting device and the third light emitting device includes a charge generation layer disposed on the first light emitting layer, a second hole transport layer disposed on the charge generation layer, and a second light emitting layer disposed on the second hole transport layer,
wherein each of the first and third light emitting devices include a second optical layer disposed between the second hole transport layer and the second light emitting layer, and
wherein the second optical layers of the first and third light emitting devices have the same thickness.

14. The display device of claim 13, wherein the second hole transport layer of the second light emitting device contacts the second light emitting layer of the second light emitting device.

15. The display device of claim 13, wherein a thickness of the first light emitting layer of the first light emitting device is greater than a thickness of the first light emitting layer of the second light emitting device.

16. A display device comprising:
a substrate including a first sub-pixel, a second sub-pixel and a third sub-pixel;
a first light emitting device disposed in the first sub-pixel;
a second light emitting device disposed in the second sub-pixel; and
a third light emitting device disposed in the third sub-pixel,
wherein each of the first light emitting device, the second light emitting device and the third light emitting device includes a first electrode disposed on the substrate, a first hole transport layer disposed on the first electrode, a first light emitting layer disposed on the first hole transport layer, a charge generation layer disposed on the first light emitting layer, a second hole transport layer disposed on the charge generation layer, and a second light emitting layer disposed on the second hole transport layer,
wherein each of the first and second light emitting devices includes a first optical layer disposed between the second hole transport layer and the second light emitting layer, and
wherein a thickness of the first optical layer of the first light emitting device is the same as a thickness of the first optical layer of the second light emitting device.

17. The display device of claim 16, wherein the first optical layer contacts a lower surface of the second light emitting layer.

18. The display device of claim 16, wherein the first light emitting device includes a second optical layer disposed between the first hole transport layer and the second light emitting layer, and
wherein the thickness of the first optical layer of the first light emitting device is different from a thickness of the second optical layer of the first light emitting device.

19. The display device of claim 1, wherein the first optical layer is continuously disposed in the first and second sub-pixels.

20. The display device of claim 19, wherein the third light emitting device includes a first optical layer disposed between the first hole transport layer and the first light emitting layer, and
wherein the first optical layer disposed in the third sub-pixel is spaced apart from the first optical layer disposed in the first sub-pixel and also spaced apart from the first optical layer disposed in the second sub-pixel.
